(19) United States
(12) Patent Application Publication
(10) Pub. No.: US 2026/0040437 A1
(43) Pub. Date: Feb. 5, 2026

(54) WIRING CIRCUIT BOARD

(71) Applicant: NITTO DENKO CORPORATION, Osaka (JP)

(72) Inventors: Takaya KOUCHI, Osaka (JP); Shusaku SHIBATA, Osaka (JP); Makiko HIRATA, Osaka (JP)

(73) Assignee: NITTO DENKO CORPORATION, Osaka (JP)

(21) Appl. No.: 19/281,003

(22) Filed: Jul. 25, 2025

(30) Foreign Application Priority Data
Jul. 31, 2024 (JP) 2024-125132

(51) Int. Cl. H05K 1/02

(52) U.S. Cl. CPC H05K 1/0275

(57) ABSTRACT

A wiring circuit board includes a wiring portion and a first support portion supporting one end portion of the wiring portion. The wiring portion has a metal support layer, a conductive layer, a first insulating layer, and a wiring. A ratio (T1/W1) of a thickness T1 of the metal support layer to a width W1 of the metal support layer is below 1. The conductive layer is disposed on a one-side surface of the metal support layer in a thickness direction of the metal support layer.

### CROSS-REFERENCE TO RELATED APPLICATION

The present application claims priority from Japanese Patent Application No. 2024-125132 filed on Jul. 31, 2024, the contents of which are hereby incorporated by reference into this application.

### TECHNICAL FIELD

The present invention relates to a wiring circuit board.

### BACKGROUND ART

Conventionally, a wiring circuit board including a plurality of wiring bodies and a connecting body which connects end portions of the plurality of wiring bodies has been known (ref: for example, Patent Document 1 below).

### CITATION LIST

### Patent Document

Patent Document 1: Japanese Unexamined Patent Publication No. 2019-212656

### SUMMARY OF THE INVENTION

### Problem to be Solved by the Invention

In the wiring circuit board described in Patent Document 1, there may be a case where a first electronic component is desired to be supported so as to be able to elastically move in a thickness direction of the wiring circuit board with respect to a second electronic component in a state where the first electronic component is fixed to one connecting body and the other connecting body is fixed to the second electronic component. In this case, it is necessary to adjust the elasticity of a wiring portion.

The present invention provides a wiring circuit board capable of easily adjusting the elasticity of a wiring portion in a thickness direction.

### Means for Solving the Problem

The present invention [1] includes a wiring circuit board including a wiring portion having a wiring extending in a first direction and extending in the first direction, and a first support portion supporting one end portion of the wiring portion in the first direction, wherein the wiring portion has a metal support layer, a conductive layer disposed on a one-side surface of the metal support layer in a thickness direction of the metal support layer, the wiring disposed at one side of the conductive layer in the thickness direction, and an insulating layer disposed between the conductive layer and the wiring in the thickness direction; and a ratio of a thickness of the metal support layer to a dimension of the metal support layer in a second direction perpendicular to both the thickness direction and the first direction is below 1.

According to such a configuration, in the wiring portion, the ratio of the thickness of the metal support layer to the dimension of the metal support layer in the second direction is below 1.

Therefore, the movement of the wiring portion in the thickness direction can be allowed, while the movement of the wiring portion in the second direction is suppressed.

Then, the wiring portion has the metal support layer, and the conductive layer disposed on the one-side surface of the metal support layer in the thickness direction.

Therefore, it is possible to adjust the elasticity of the wiring portion in the thickness direction by the conductive layer, while the elasticity of the wiring portion in the thickness direction is ensured by the metal support layer.

As a result, it is possible to easily adjust the elasticity of the wiring portion in the thickness direction.

The present invention [2] includes the wiring circuit board described in the above-described [1], wherein the metal support layer has a thickness of 30 μm or more.

According to such a configuration, it is possible to ensure the elasticity of the wiring portion in the thickness direction.

The present invention [3] includes the wiring circuit board described in the above-described or [2], wherein the conductive layer has a thickness of 1 μm or more.

According to such a configuration, it is possible to adjust the elasticity of the wiring portion in the thickness direction.

The present invention [4] includes the wiring circuit board described in any one of the above-described [1] to [3], wherein the ratio of the thickness of the conductive layer to the thickness of the metal support layer is one-thirtieth to one-third.

According to such a configuration, it is possible to adjust the elasticity of the wiring portion in the thickness direction, while the elasticity of the wiring portion in the thickness direction is ensured.

The present invention [5] includes the wiring circuit board described in any one of the above-described [1] to [4], wherein the ratio of the dimension of the conductive layer in the second direction to the dimension of the metal support layer in the second direction is one-half or more.

According to such a configuration, it is possible to adjust the elasticity of the wiring portion in the thickness direction.

The present invention [6] includes the wiring circuit board described in any one of the above-described [1] to [5] further including a second support portion supporting the other end portion of the wiring portion in the first direction.

The present invention [7] includes the wiring circuit board described in any one of the above-described [1] to [6] including the wiring, a first circuit pattern having a first terminal connected to the wiring, and a second circuit pattern having a second terminal connected to the conductive layer and independent from the first circuit pattern.

According to such a configuration, it is possible to design a circuit independent from the first circuit pattern by using the conductive layer.

Therefore, it is possible to increase a degree of freedom in circuit design, while the elasticity of the wiring portion in the thickness direction can be adjusted.

### Effect of the Invention

According to the wiring circuit board of the present invention, it is possible to easily adjust the elasticity of the wiring portion in the thickness direction.

### BRIEF DESCRIPTION OF THE DRAWINGS

FIG. 1 shows a plan view of a wiring circuit board as one embodiment of the present invention, and in FIG. 1, a second insulating layer is omitted.

FIG. 2A shows an A-A cross-sectional view of the wiring circuit board shown in FIG. 1.

FIG. 2B shows a B-B cross-sectional view of the wiring circuit board shown in FIG. 1.

FIGS. 3A and 3B show views for illustrating a mounting state of the wiring circuit board shown in FIG. 2A:

FIG. 3A illustrating a state where a first electronic component is fixed to a first support portion and a second support portion is fixed to a second electronic component and

FIG. 3B illustrating a state where the first electronic component moves with respect to the second electronic component in a thickness direction.

FIGS. 4A to 4D show process views for illustrating a method for producing the wiring circuit board shown in FIG. 2B:

FIG. 4A illustrating a conductive layer forming step,

FIG. 4B illustrating a first insulating layer forming step,

FIG. 4C illustrating a circuit pattern forming step, and

FIG. 4D illustrating a second insulating layer forming step.

FIG. 5 shows a plan view of a wiring circuit board of a modified example (1).

FIG. 6 shows a plan view of a wiring circuit board of a modified example (2).

FIG. 7 shows a plan view of a wiring circuit board of a modified example (3).

FIG. 8 shows a C-C cross-sectional view of the wiring circuit board shown in FIG. 7.

FIGS. 9A and 9B show process views for illustrating an electrically conductive layer forming step of a method for producing a wiring circuit board of a modified example (4):

FIG. 9A illustrating a step of preparing a metal-clad laminate and

FIG. 9B illustrating a step of forming a conductive layer by etching the metal-clad laminate.

### DESCRIPTION OF EMBODIMENTS

### 1. Wiring Circuit Board

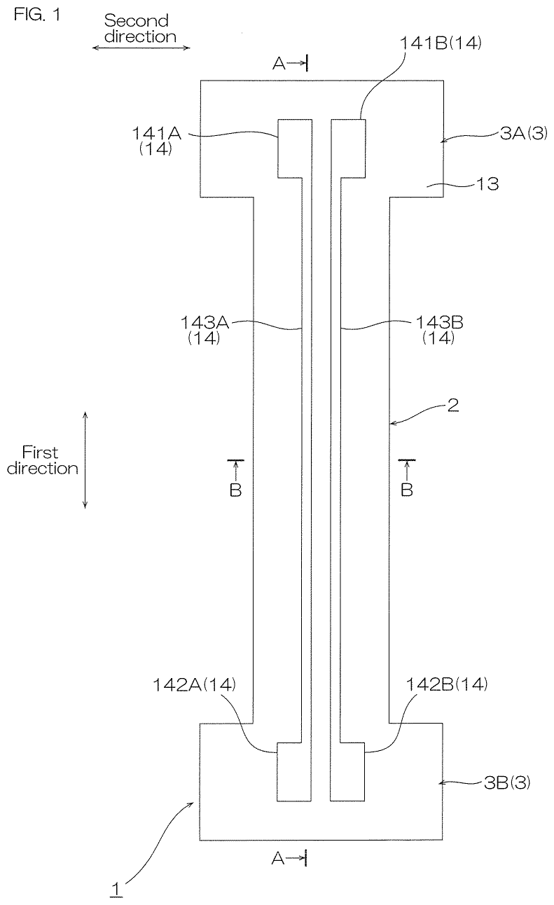

As shown in FIG. 1, a wiring circuit board 1 includes a wiring portion 2 and a plurality of support portions 3 (in the present embodiment, a first support portion 3A and a second support portion 3B).

The wiring portion 2 is disposed between the first support portion 3A and the second support portion 3B in a first direction. The wiring portion 2 extends in the first direction. Specifically, the wiring portion 2 has a width in a second direction, and extends in the first direction. Wirings 143A and 143B to be described later extend in the first direction in the wiring portion 2. That is, the wiring portion 2 has the width in the second direction, and extends in a direction in which the wirings 143A and 143B extend. The first direction is perpendicular to a thickness direction of the wiring circuit board 1. The second direction is perpendicular to both the thickness direction and the first direction. One end portion of the wiring portion 2 in the first direction is connected to the first support portion 3A. The other end portion of the wiring portion 2 in the first direction is connected to the second support portion 3B. A shape of the wiring portion 2 is not limited. The wiring portion 2 may be linear or curved. At least a portion of the wirings 143A and 143B is disposed in the wiring portion 2.

The first support portion 3A and the second support portion 3B are disposed spaced from each other in the first direction. The shape of the first support portion 3A and the second support portion 3B is not limited. The first support portion 3A supports one end portion of the wiring portion 2 in the first direction. Terminals 141A and 141B to be described later may be also disposed in the first support portion 3A. The second support portion 3B supports the other end portion of the wiring portion 2 in the first direction. Terminals 142A and 142B to be described later may be also disposed in the second support portion 3B.

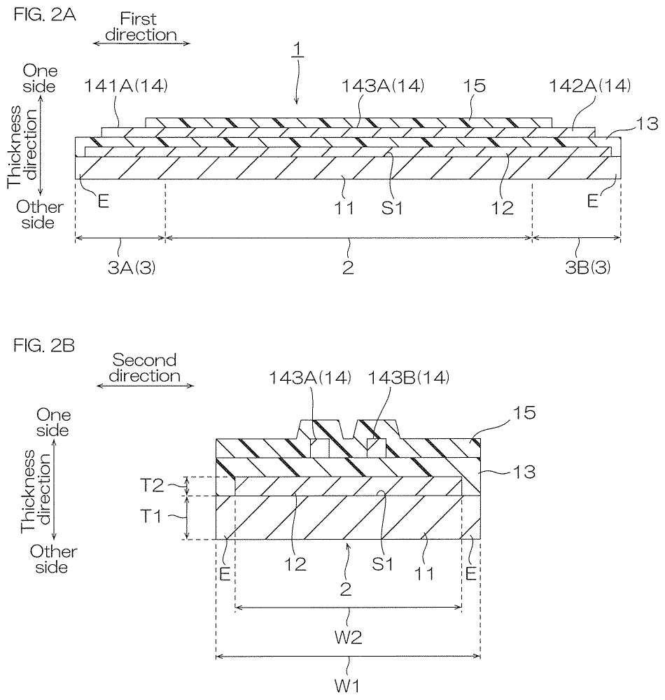

As shown in FIG. 2A, the wiring circuit board 1 includes a metal support layer 11, a conductive layer 12, a first insulating layer 13, a circuit pattern 14, and a second insulating layer 15.

### (1) Metal Support Layer

The metal support layer 11 is disposed in the wiring portion 2 and the support portion 3 (the first support portion 3A and the second support portion 3B). That is, the wiring portion 2 has the metal support layer 11. The metal support layer 11 supports the first insulating layer 13, the circuit pattern 14, and the second insulating layer 15.

A Young's modulus of the metal support layer 11 is, for example, 100 GPa or more, preferably 130 GPa or more, more preferably 170 GPa or more. When the Young's modulus of the metal support layer 11 is the above-described lower limit value or more, it is possible to ensure the elasticity of the wiring portion 2 in the thickness direction. The Young's modulus of the metal support layer 11 is, for example, 250 GPa or less, preferably 210 GPa or less. When the Young's modulus of the metal support layer 11 is the above-described upper limit value or less, it is possible to ensure the flexibility of the wiring portion 2 in the thickness direction. The Young's modulus of the metal support layer 11 is, for example, 100 GPa to 250 GPa, preferably 130 GPa to 210 GPa, more preferably 170 GPa to 210 GPa. When the Young's modulus of the metal support layer 11 is within the above-described range, it is possible to achieve both the elasticity of the wiring portion 2 and the flexibility of the wiring portion 2 in the thickness direction.

Examples of a material for the metal support layer 11 include copper, nickel, cobalt, titanium, iron, and alloys of these. Examples of the alloy include copper alloys and stainless steel. As the material for the metal support layer 11, preferably, stainless steel is used.

As shown in FIG. 2B, a thickness T1 of the metal support layer 11 is, for example, thicker than 30 μm, and preferably 35 μm or more. When the thickness T1 of the metal support layer 11 is the above-described lower limit value or more, it is possible to ensure the elasticity of the wiring portion 2 in the thickness direction. The thickness T1 of the metal support layer 11 is, for example, 100 μm or less, preferably 90 μm or less. When the thickness T1 of the metal support layer 11 is the above-described upper limit value or less, it is possible to ensure the flexibility of the wiring portion 2 in the thickness direction. The thickness T1 of the metal support layer 11 is, for example, thicker than 30 μm, and 100 μm or less, preferably 35 μm to 90 μm. When the thickness T1 of the metal support layer 11 is within the above-described range, it is possible to achieve both the elasticity of the wiring portion 2 and the flexibility of the wiring portion 2 in the thickness direction.

A width W1 (dimension of the metal support layer 11 in the second direction) of the metal support layer 11 is larger than the thickness T1 of the metal support layer 11. The width W1 of the metal support layer 11 is, for example, larger than 30 μm, and preferably 50 μm or more, more preferably 100 μm or more. When the width W1 of the metal support layer 11 is the above-described lower limit value or more, it is possible to ensure the rigidity of the wiring portion 2 in the second direction. The upper limit value of the width W1 of the metal support layer 11 is not limited. The width W1 of the metal support layer 11 is, for example, 1000 μm or less, preferably 800 μm or less.

A ratio (T1/W1) of the thickness T1 of the metal support layer 11 to the width W1 of the metal support layer 11 is below 1, preferably 0.5 or less. When the ratio (T1/W1) is the above-described lower limit value or more, the movement of the wiring portion 2 in the thickness direction can be allowed, while the movement of the wiring portion 2 in the second direction is suppressed. The lower limit value of the ratio (T1/W1) is not limited. The ratio (T1/W1) is, for example, 0.01 or more, preferably 0.02 or more.

### (2) Conductive Layer

As shown in FIG. 2A, the conductive layer 12 is disposed in the wiring portion 2 and the support portion 3 (the first support portion 3A and the second support portion 3B). That is, the wiring portion 2 has the conductive layer 12. The conductive layer 12 reinforces the metal support layer 11. The conductive layer 12 is disposed on a one-side surface S1 of the metal support layer 11 in the thickness direction of the metal support layer 11. The conductive layer 12 is preferably disposed on the one-side surface S1 of the metal support layer 11 via a bonding layer which bonds the metal support layer 11 to the conductive layer 12. In other words, the bonding layer is preferably disposed between the metal support layer 11 and the conductive layer 12. The bonding layer is made of metal. The bonding layer is, for example, a sputtering layer. Examples of the material for the bonding layer include chromium, nickel, titanium, and alloys of these. The conductive layer 12 does not have a wiring pattern.

The conductive layer 12 is overlapped with the entire circuit pattern 14 in the thickness direction. The conductivity of the conductive layer 12 is higher than the conductivity of the metal support layer 11. Therefore, it is possible to reduce a transmission loss of the circuit pattern 14. Examples of the material for the conductive layer 12 include copper, silver, gold, iron, aluminum, chromium, and alloys of these. The conductive layer 12 is preferably made of copper. The conductive layer 12 is a plating layer. Therefore, it is possible to easily adjust a thickness T2 (ref: FIG. 2B) of the conductive layer 12. Therefore, it is possible to more easily adjust the elasticity of the wiring portion 2 in the thickness direction.

As shown in FIG. 2B, the thickness T2 of the conductive layer 12 is, for example, 1 μm or more, preferably 2 μm or more. When the thickness T2 of the conductive layer 12 is the above-described lower limit value or more, it is possible to ensure the electrical conductivity of the conductive layer 12, while the elasticity of the wiring portion 2 is adjusted in the thickness direction. The thickness T2 of the conductive layer 12 is, for example, 30 μm or less, preferably m or less. When the thickness T2 of the conductive layer 12 is the above-described upper limit value or less, it is possible to ensure the flexibility of the wiring portion 2 in the thickness direction.

The ratio (T2/T1) of the thickness T2 of the conductive layer 12 to the thickness T1 of the metal support layer 11 is, for example, one-thirtieth to one-third, preferably one-fifteenth to one-fourth. When the ratio (T2/T1) is within the above-described range, it is possible to ensure the electrical conductivity of the conductive layer 12, while the elasticity of the wiring portion 2 in the thickness direction is adjusted.

As shown in FIGS. 2A and 2B, the conductive layer 12 covers the entire one-side surface S1 of the metal support layer 11 except for an outer peripheral end portion E of the metal support layer 11. The conductive layer 12 may also cover the entire one-side surface S1 of the metal support layer 11 including the outer peripheral end portion E of the metal support layer 11. As shown in FIG. 2B, in the wiring portion 2, the ratio (W2/W1) of a width W2 (dimension of the conductive layer 12 in the second direction) of the conductive layer 12 to the width W1 (dimension of the metal support layer 11 in the second direction) of the metal support layer 11 is, for example, one-half or more, preferably two-thirds or more, more preferably four-fifths or more, further more preferably nine-tenths or more. The width W2 of the conductive layer 12 may be the same as the width W1 of the metal support layer 11. The ratio (W2/W1) is, for example, 1 or less, preferably ninety nine-hundredths or less.

### (3) First Insulating Layer

As shown in FIG. 2A, the first insulating layer 13 is disposed in the wiring portion 2 and the support portion 3 (the first support portion 3A, the second support portion 3B). That is, the wiring portion 2 has the first insulating layer 13. The first insulating layer 13 is disposed at one side of the metal support layer 11 in the thickness direction. The first insulating layer 13 is disposed on the one-side surface S1 of the metal support layer 11 in the thickness direction. The first insulating layer 13 covers the conductive layer 12. The first insulating layer 13 is disposed between the conductive layer 12 and the circuit pattern 14 in the thickness direction. That is, as shown in FIG. 2B, the first insulating layer 13 of the wiring portion 2 is disposed between the conductive layer 12 and the wirings 143A and 143B in the thickness direction. The first insulating layer 13 insulates the conductive layer 12 from the circuit pattern 14.

Preferably, a protective metal layer which protects the metal support layer 11 and the conductive layer 12 is disposed between the metal support layer 11 and the first insulating layer 13, and between the conductive layer 12 and the first insulating layer 13. The protective metal layer is made of metal. The protective metal layer is, for example, the sputtering layer. Examples of a material for the protective metal layer include chromium, nickel, titanium, and alloys of these.

The first insulating layer 13 is made of resin. Examples of the resin include polyimide, maleimide, epoxy resins, polybenzoxazole, and polyester. Preferably, the first insulating layer 13 is made of polyimide.

The first insulating layer 13 has the thickness of, for example, 1 μm to 30 μm, preferably 3 μm to 25 μm.

### (4) Circuit Pattern

The circuit pattern 14 is disposed at one side of the conductive layer 12 in the thickness direction. That is, in the wiring portion 2, the wirings 143A and 143B are disposed at one side of the conductive layer 12 in the thickness direction. The circuit pattern 14 is disposed away from the conductive layer 12 in the thickness direction. The circuit pattern 14 is independent from the conductive layer 12. The circuit pattern 14 is disposed on one side of the first insulating layer 13 in the thickness direction. The circuit pattern 14 is disposed on the one-side surface of the first insulating layer 13 in the thickness direction. The circuit pattern 14 is disposed at the opposite side of the conductive layer 12 with respect to the first insulating layer 13 in the thickness direction. The circuit pattern 14 is made of metal. Examples of the metal include copper, silver, gold, iron, aluminum, chromium, and alloys of these. The circuit pattern 14 is preferably made of copper. The shape of the circuit pattern 14 is not limited.

As shown in FIG. 1, the circuit pattern 14 has the plurality of terminals 141A and 141B, the plurality of terminals 142A and 142B, and the plurality of wirings 143A and 143B.

### (4-1) Terminal

The terminals 141A and 141B are disposed in the first support portion 3A. Each of the terminals 141A and 141B has a generally rectangular shape. In the present embodiment, the terminals 141A and 141B are aligned in the second direction. The terminals 141A and 141B are disposed spaced from each other in the second direction. The direction in which the terminals 141A and 141B are aligned is not limited to the second direction. The terminal 141A is connected to one end portion of the wiring 143A. The terminal 141B is connected to one end portion of the wiring 143B.

The terminals 142A and 142B are disposed in the second support portion 3B. Each of the terminals 142A and 142B has the generally rectangular shape. The terminals 142A and 142B are aligned in the second direction. The terminals 142A and 142B are disposed spaced from each other in the second direction. The direction in which the terminals 142A and 142B are aligned is not limited to the second direction. The terminal 142A is connected to the other end portion of the wiring 143A. The terminal 142B is connected to the other end portion of the wiring 143B.

### (4-2) Wiring

At least a portion of each of the wirings 143A and 143B is disposed in the wiring portion 2. That is, the wiring portion 2 has the wirings 143 A and 143 B. Each of the wirings 143A and 143B extends in the first direction in the wiring portion 2. The wirings 143A and 143B are aligned in the second direction in the wiring portion 2. The wirings 143A and 143B are disposed spaced from each other in the second direction. The wiring 143 A electrically connects the terminal 141 A to the terminal 142 A. The wiring 143B electrically connects the terminal 141B to the terminal 142B.

Each of the wirings 143A and 143B has the thickness of, for example, 5 μm to 50 μm, preferably 7 μm to 45 μm.

### (5) Second Insulating Layer

As shown in FIG. 2A, the second insulating layer 15 is disposed at least in the wiring portion 2. That is, the wiring portion 2 has the second insulating layer 15. The second insulating layer 15 may be also disposed, if necessary, in the support portion 3 (the first support portion 3A, the second support portion 3B). The second insulating layer 15 does not cover the terminals 141A, 141B, 142A, and 142B.

As shown in FIG. 2B, the second insulating layer 15 covers all of the wirings 143A and 143B. The second insulating layer 15 is disposed on the first insulating layer 13 in the thickness direction. The second insulating layer 15 is made of resin. Examples of the resin include polyimide, maleimide, epoxy resins, polybenzoxazole, and polyester. Preferably, the second insulating layer 15 is made of polyimide.

The second insulating layer 15 has the thickness of, for example, 1 μm to 30 μm, preferably 3 μm to 25 μm.

### 2. Mounting State of Wiring Circuit Board

Next, a mounting state of the wiring circuit board 1 is described.

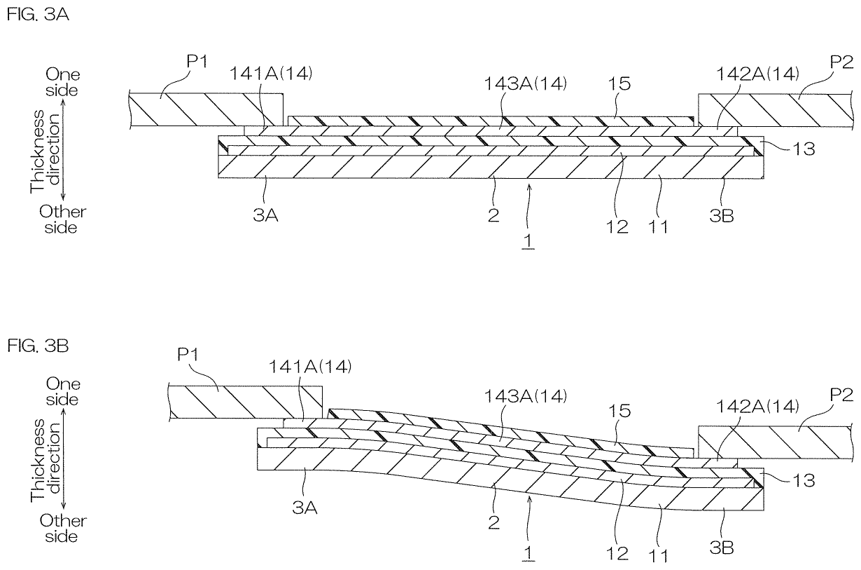

As shown in FIG. 3A, the wiring circuit board 1 is used for electrical connection of a first electronic component P1 and a second electronic component P2. For example, the first electronic component P1 is fixed to the first support portion 3A. The wiring circuit board 1 is fixed to the second electronic component P2 in the second support portion 3B. The wiring portion 2 is disposed between the first electronic component P1 and the second electronic component P2.

Then, as shown in FIG. 3B, the first electronic component P1 is movable in the thickness direction with respect to the second electronic component P2 against the elasticity of the wiring portion 2.

### 3. Method for Producing Wiring Circuit Board

Next, a method for producing the wiring circuit board 1 is described.

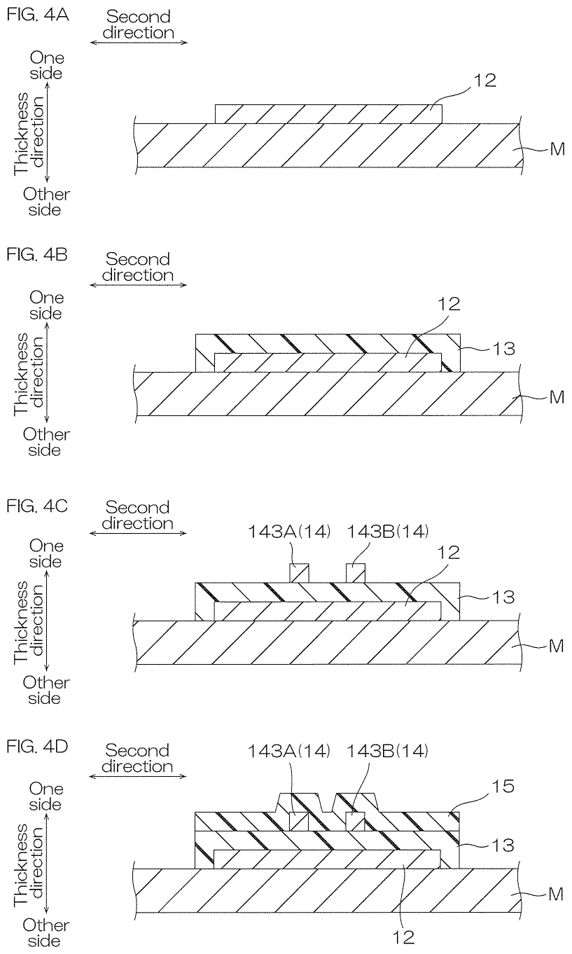

The method for producing the wiring circuit board 1 includes a conductive layer forming step (ref: FIG. 4A), a first insulating layer forming step (ref: FIG. 4B), a circuit pattern forming step (ref: FIG. 4C), a second insulating layer forming step (ref: FIG. 4D), and an outer shape processing step (ref: FIG. 2B).

### (1) Conductive Layer Forming Step

As shown in FIG. 4A, in the conductive layer forming step, the conductive layer 12 is formed on the one-side surface of a metal substrate M.

Specifically, first, in the thickness direction, the above-described bonding layer is formed on the one-side surface of the substrate M. The bonding layer is, for example, formed by sputtering.

Next, the bonding layer is covered with plating resist.

Next, the plating resist is exposed to light and developed. Then, the plating resist of the portion where the conductive layer 12 is to be formed is removed, and the bonding layer is exposed to the portion where the conductive layer 12 is to be formed. On the other hand, the plating resist of the portion where the conductive layer 12 is to be not formed remains.

Next, the conductive layer 12 is formed on the exposed bonding layer by electrolytic plating. After the electrolytic plating is completed, the plating resist is peeled.

Thus, the conductive layer 12 is formed on the substrate M.

### (2) First Insulating Layer Forming Step

Next, as shown in FIG. 4B, in the first insulating layer forming step, the first insulating layer 13 is formed on the one-side surface of the substrate M.

Specifically, in the first insulating layer forming step, first, in the thickness direction, the above-described protective metal layer is formed on the one-side surface of the substrate M and the conductive layer 12. The protective metal layer is, for example, formed by the sputtering.

Next, a solution (varnish) of a photosensitive resin is coated onto the substrate M and the conductive layer 12 to be dried, thereby forming a coating film of the photosensitive resin. Next, the coating film of the photosensitive resin is exposed to light and developed. Thus, the first insulating layer 13 is obtained.

### (3) Circuit Pattern Forming Step

Next, as shown in FIG. 4C, in the circuit pattern forming step, the circuit pattern 14 is formed on the first insulating layer 13.

Specifically, first, in the thickness direction, a seed layer is formed on the one-side surface of the first insulating layer 13, and on the one-side surface of the substrate M. The seed layer is, for example, formed by the sputtering. Examples of the material for the seed layer include chromium, copper, nickel, titanium, and alloys of these.

Next, the seed layer is covered with the plating resist.

Next, the plating resist is exposed to light and developed. Then, the plating resist of the portion where the circuit pattern 14 is to be formed is removed, and the seed layer is exposed to the portion where the circuit pattern 14 is to be formed. On the other hand, the plating resist of the portion where the circuit pattern 14 is not to be formed remains.

Next, the circuit pattern 14 is formed on the exposed seed layer by the electrolytic plating. After the electrolytic plating is completed, the plating resist is peeled, and the seed layer exposed by peeling of the plating resist is removed by etching.

Thus, the circuit pattern 14 is formed on the first insulating layer 13.

### (4) Second Insulating Layer Forming Step

Next, as shown in FIG. 4D, in the second insulating layer forming step, the second insulating layer 15 is formed on the first insulating layer 13.

Specifically, in the second insulating layer forming step, first, the solution (varnish) of the photosensitive resin is coated onto the substrate M, the first insulating layer 13, and the circuit pattern 14 to be dried, thereby forming the coating film of the photosensitive resin.

Next, the coating film of the photosensitive resin is exposed to light and developed. Thus, the second insulating layer 15 is formed on the first insulating layer 13.

### (5) Outer Shape Processing Step

Next, as shown in FIG. 2B, in the outer shape processing step, the substrate M is etched, thereby forming the outer shape of the metal support layer 11.

As described above, the above-described wiring circuit board 1 is obtained.

### 4. Function and Effect

(1) According to the wiring circuit board 1, as shown in FIG. 2B, in the wiring portion 2, the ratio (T1/W1) of the thickness T1 of the metal support layer 11 to the width W1 of the metal support layer 11 is below 1.

Therefore, the movement of the wiring portion 2 in the thickness direction can be allowed, while the movement of the wiring portion 2 in the second direction is suppressed.

Then, the wiring portion 2 has the metal support layer 11 and the conductive layer 12 disposed on the one-side surface S1 of the metal support layer 11 in the thickness direction.

Therefore, it is possible to adjust the elasticity of the wiring portion 2 in the thickness direction by the conductive layer 12, while the elasticity of the wiring portion 2 in the thickness direction is ensured by the metal support layer 11.

As a result, it is possible to easily adjust the elasticity of the wiring portion 2 in the thickness direction.

(2) According to the wiring circuit board 1, the thickness T1 of the metal support layer 11 is thicker than 30 km.

Therefore, it is possible to ensure the elasticity of the wiring portion 2 in the thickness direction.

(3) According to the wiring circuit board 1, the thickness T2 of the conductive layer 12 is 1 m or more.

Therefore, it is possible to adjust the elasticity of the wiring portion 2 in the thickness direction.

(4) According to the wiring circuit board 1, the ratio (T2/T1) of the thickness T2 of the conductive layer 12 to the thickness T1 of the metal support layer 11 is one-thirtieth to one-third.

Therefore, it is possible to adjust the elasticity of the wiring portion 2 in the thickness direction, while the elasticity of the wiring portion 2 in the thickness direction is ensured.

(5) According to the wiring circuit board 1, the ratio (W2/W1) of the width W2 of the conductive layer 12 to the width W1 of the metal support layer 11 is one-half or more.

Therefore, it is possible to adjust the elasticity of the wiring portion 2 in the thickness direction.

### 5. Modified Examples

Next, modified examples are described. In each modified example, the same reference numerals are provided for members corresponding to each of those in the above-described embodiment, and their detailed description is omitted.

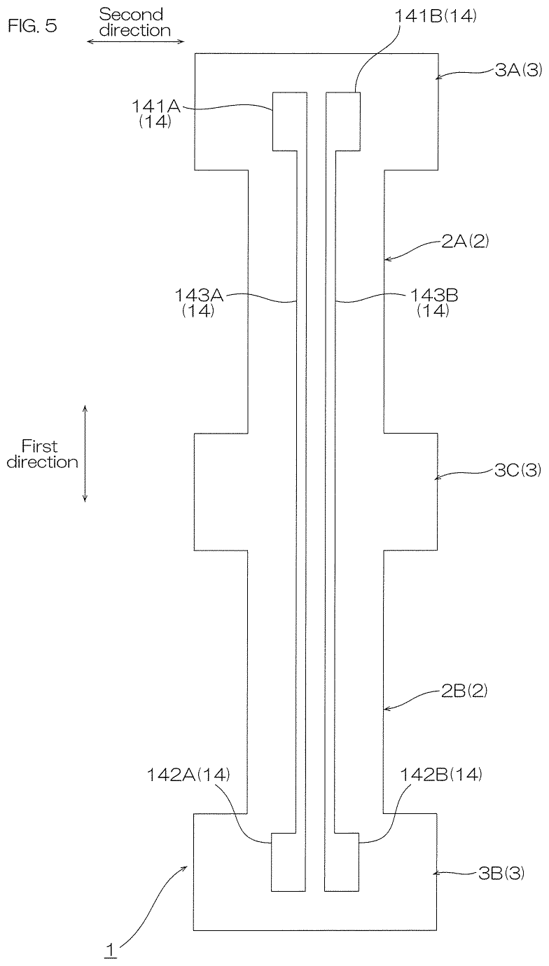

(1) The wiring circuit board 1 may also have three or more support portions 3. For example, as shown in FIG. 5, the wiring circuit board 1 may also have a third support portion 3C in addition to the first support portion 3A and the second support portion 3B described above. In this case, the wiring circuit board 1 has a plurality of wiring portions 2A and 2B.

Each of the wirings 143A and 143B extends from the first support portion 3A to the second support portion 3B through the third support portion 3C. A middle portion of each of the wirings 143A and 143B is disposed in the third support portion 3C.

The third support portion 3C is disposed between the first support portion 3A and the second support portion 3B in the first direction. The third support portion 3C supports the other end portion of the wiring portion 2A, and one end portion of the wiring portion 2B. The wiring portions 2A and 2B have the same structure as the wiring portion 2 of the embodiment described above.

In this modified example, the middle portions of the wirings 143A and 143B can be supported by the third support portion 3C.

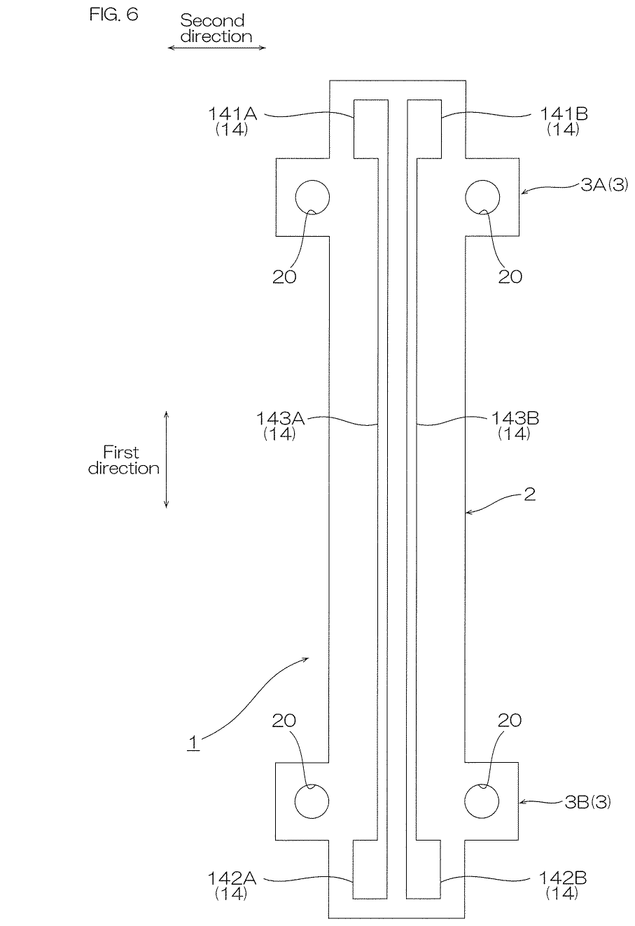

(2) As shown in FIG. 6, the terminals 141A and 141B may not be also disposed in the first support portion 3A. The terminals 142A and 142B may not be also disposed in the second support portion 3B. The first support portion 3A may be also disposed between the terminals 141A and 141B and the wiring portion 2 in the first direction. The second support portion 3B may be also disposed between the terminals 142A and 142B and the wiring portion 2 in the first direction. Each of the first support portion 3A and the second support portion 3B may also have a through hole 20. A fixture such as screw and pin passes through the through hole 20.

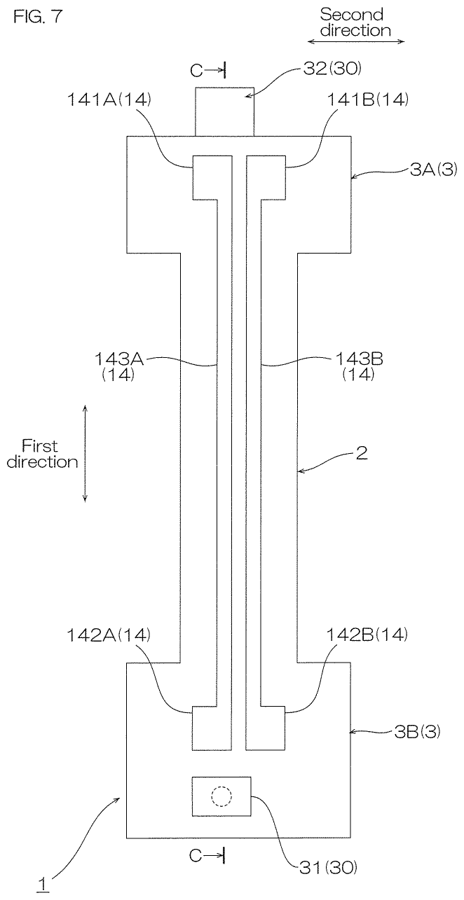

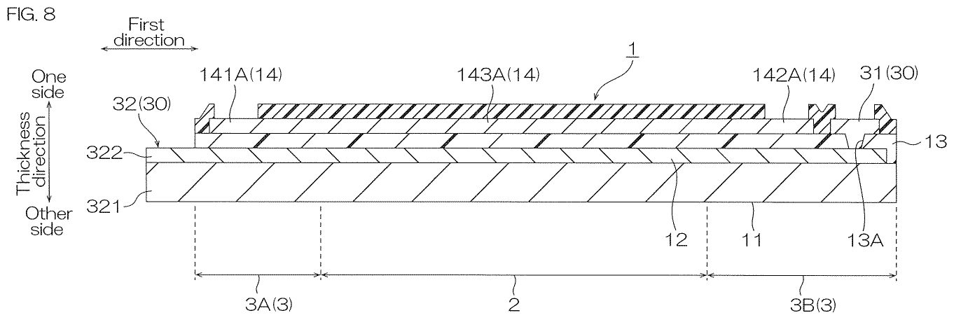

(3) As shown in FIGS. 7 and 8, the wiring circuit board 1 may also include the above-described circuit pattern 14 (first circuit pattern) and a second circuit pattern 30 which is independent from the circuit pattern 14.

The second circuit pattern 30 has a terminal 31 and a terminal 32. The second circuit pattern 30 functions as an electrical circuit independent from the circuit pattern 14 by the terminal 31 and the terminal 32 being electrically connected via the conductive layer 12 (ref: FIG. 8).

As shown in FIG. 7, the terminal 31 is, for example, disposed in the second support portion 3B. The terminal 31 has, for example, generally the rectangular shape. A position and the shape of the terminal 31 are not limited. As shown in FIG. 8, the terminal 31 is disposed on one side of the first insulating layer 13 in the thickness direction. The terminal 31 is electrically connected to the conductive layer 12 through a through hole 13A of the first insulating layer 13.

As shown in FIG. 7, the terminal 32 is disposed away from the terminal 31 in the first direction. The terminal 32 may be also, for example, disposed at the opposite side of the wiring portion 2 with respect to the first support portion 3A in the first direction. The terminal 32 may also protrude from the first support portion 3A in the first direction. The terminal 32 may also have a generally prismatic column shape. The position and the shape of the terminal 32 are not limited. As shown in FIG. 8, the terminal 32 is continuous with the metal support layer 11 and the conductive layer 12. Thus, the terminal 32 is electrically connected to the conductive layer 12. The terminal 32 may also have a metal layer 321 which is continuous with the metal support layer 11 and a terminal conductive layer 322 which is continuous with the conductive layer 12. The metal layer 321 is, for example, made of the same material as the metal support layer 11. The terminal conductive layer 322 is, for example, made of the same material as the conductive layer 12.

According to this modified example, it is possible to design a circuit independent from the first circuit pattern by using the conductive layer 12.

Therefore, it is possible to increase a degree of freedom in circuit design, while the elasticity of the wiring portion 2 in the thickness direction can be adjusted.

(4) The method for forming the conductive layer 12 is not limited to plating. For example, in the above-described conductive layer forming step, the conductive layer 12 may be also formed by etching a metal-clad laminate.

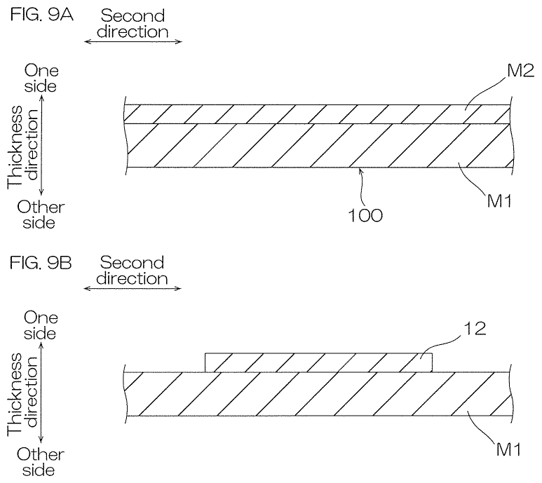

Specifically, as shown in FIG. 9A, a metal-clad laminate 100 in which a metal layer M2 is formed on a metal substrate M1 is prepared. The substrate M1 is made of the material for the metal support layer 11 described above. The metal layer M2 is made of the material for the conductive layer 12 described above.

Next, the metal layer M2 is covered with etching resist.

Next, the etching resist is exposed to light and developed. Then, the etching resist of the portion where the conductive layer 12 is formed remains, and the etching resist of the portion where the conductive layer 12 is not formed is removed.

Next, the metal layer M2 of the portion where the conductive layer 12 is not formed is removed by an etching solution. After the etching is completed, the etching resist is peeled.

Thus, as shown in FIG. 9B, the conductive layer 12 is formed on the substrate M1.

Thereafter, the first insulating layer forming step (ref: FIG. 4B), the circuit pattern forming step (ref: FIG. 4C), the second insulating layer forming step (ref: FIG. 4D), and the outer shape processing step (ref: FIG. 2B) are carried out in order in the same manner as the above-described embodiment, thereby obtaining the wiring circuit board 1.

(5) The above-described terminal 141A may also have a plurality of conductive layers. For example, the terminal 141A may also have a first conductive layer and a second conductive layer. The first conductive layer is disposed on the first insulating layer 13. The wiring 143A is connected to the first conductive layer of the terminal 141A. As the material for the first conductive layer, for example, the same material as the circuit pattern 14 described above is used. The second conductive layer is disposed on the first conductive layer. The second conductive layer may be also made of the same material as the first conductive layer. The second conductive layer may be also made of a material different from the first conductive layer (for example, solder).

Further, the above-described terminal 141A may also have a covering layer which covers the surface of the conductive layer. The covering layer has at least a surface layer. The surface layer is, for example, made of gold. The surface layer may be also an electroless gold plating layer. The covering layer preferably has an intermediate layer. The covering layer may also not have the intermediate layer. The intermediate layer is disposed between the conductive layer and the surface layer. The intermediate layer is, for example, made of nickel. The intermediate layer may be also an electroless nickel plating layer.

The same applies to the terminals 141B, 142A, and 142B.

(6) In the above-described modified examples (1) to (5), the same function and effect as the above-described embodiment can be obtained.

While the illustrative embodiments of the present invention are provided in the above description, such is for illustrative purpose only and it is not to be construed as limiting the scope of the present invention. Modification and variation of the present invention that will be obvious to those skilled in the art is to be covered by the following claims.

### INDUSTRIAL APPLICATION

A wiring circuit board of the present invention is available in connection of electronic components.

### DESCRIPTION OF REFERENCE NUMERALS

1 Wiring circuit board
2 Wiring portion
3A First support portion
3B Second support portion
11 Metal support layer
12 Conductive layer
13 First insulating layer (one example of insulating layer)
14 Circuit pattern (one example of first circuit pattern)
141A Terminal (one example of first terminal)
143A Wiring
30 Second circuit pattern
31 Terminal (one example of second terminal)
S1 One-side surface of metal support layer
T1 Thickness of metal support layer
T2 Thickness of conductive layer
W1 Dimension of metal support layer in second direction
W2 Dimension of conductive layer in second direction

1. A wiring circuit board comprising:
a wiring portion having a wiring extending in a first direction and extending in the first direction, and
a first support portion supporting one end portion of the wiring portion in the first direction, wherein
the wiring portion has
a metal support layer,
a conductive layer disposed on a one-side surface of the metal support layer in a thickness direction of the metal support layer,
the wiring disposed at one side of the conductive layer in the thickness direction, and
an insulating layer disposed between the conductive layer and the wiring in the thickness direction; and
a ratio of a thickness of the metal support layer to a dimension of the metal support layer in a second direction perpendicular to both the thickness direction and the first direction is below 1.

2. The wiring circuit board according to claim 1, wherein
the metal support layer has a thickness of 30 μm or more.

3. The wiring circuit board according to claim 1, wherein
the conductive layer has a thickness of 1 μm or more.

4. The wiring circuit board according to claim 1, wherein
the ratio of the thickness of the conductive layer to the thickness of the metal support layer is one-thirtieth to one-third.

5. The wiring circuit board according to claim 1, wherein
the ratio of the dimension of the conductive layer in the second direction to the dimension of the metal support layer in the second direction is one-half or more.

6. The wiring circuit board according to claim 1 further comprising:
a second support portion supporting the other end portion of the wiring portion in the first direction.

7. The wiring circuit board according to claim 1 comprising:
the wiring, a first circuit pattern having a first terminal connected to the wiring, and
a second circuit pattern having a second terminal connected to the conductive layer and independent from the first circuit pattern.
